(19) United States
(12) Patent Application Publication
(10) Pub. No.: US 2024/0431092 A1
(43) Pub. Date: Dec. 26, 2024

(54) MEMORY CELL WITH TRANSISTOR HAVING INCREASED LEAKAGE CURRENT

(71) Applicant: Intel Corporation, Santa Clara, CA (US)

(72) Inventors: Abhishek A. Sharma, Portland, OR (US); Wilfred Gomes, Portland, OR (US); Tahir Ghani, Portland, OR (US); Anand S. Murthy, Portland, OR (US)

(73) Assignee: Intel Corporation, Santa Clara, CA (US)

(21) Appl. No.: 18/338,440

(22) Filed: Jun. 21, 2023

(51) Int. Cl. H10B 12/00

(52) U.S. Cl. CPC H10B 12/20

(57) ABSTRACT

A transistor may include a source region, a drain region, a channel region between the source region and the drain region in a first direction, a gate electrode, a source contact, and a drain contact. A first portion of the gate electrode is over the channel region in a second direction substantially perpendicular to the first direction. A second portion of the gate electrode is over a first portion of the drain region in the second direction. The source contact is over at least part of the source region. The drain contact is over a second portion of the drain region. A distance from an edge of the first portion of the drain region to an edge of the gate electrode or to an edge the first trench electrode in the first direction is greater than a fourth of a length of the gate electrode in the first direction.

### BACKGROUND

Embedded memory is important to the performance of modern system-on-a-chip (SoC) technology. Low power and high-density embedded memory cells are used in many different computer products and further improvements are always desirable. Floating body random-access memory (RAM) is a popular choice for various types of computer systems. A memory cell in floating body RAM (also referred to as “floating body cell”) may use the floating body of a single transistor to store data. Floating body cells are considered more advantageous than traditional memory cells given their simple structure and high scalability.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example IC device including a FEOL section and a BEOL section, according to some embodiments of the disclosure.

FIG. 2 illustrates another example transistor with increased GIDL current, where a gate electrode is at an opposite side from trench contacts, according to some embodiments of the disclosure.

FIG. 3 illustrates an example transistor with increased GIDL current, where a gate electrode is at an opposite side from trench contacts, according to some embodiments of the disclosure.

FIG. 4 illustrates an example transistor with increased GIDL current, where trench contacts are at opposite sides, according to some embodiments of the disclosure.

FIG. 5 illustrates an example vertical transistor with increased GIDL current, according to some embodiments of the disclosure.

FIG. 6 illustrates an example transistor with materials of different band gaps, according to some embodiments of the disclosure.

FIG. 7 illustrates another example transistor with materials of different band gaps, according to some embodiments of the disclosure.

FIG. 8 illustrates an example transistor with asymmetric source and drain regions, according to some embodiments of the disclosure.

FIG. 9 illustrates an example transistor with a hybrid gate, according to some embodiments of the disclosure.

FIGS. 10A-10B are top views of a wafer and dies that may facilitate memory cells with transistors having increased leakage current, according to some embodiments of the disclosure.

FIG. 11 is a side, cross-sectional view of an example IC package that may include one or more IC devices having transistors having increased leakage current, according to some embodiments of the disclosure.

FIG. 12 is a cross-sectional side view of an IC device assembly that may include components having one or more IC devices implementing transistors having increased leakage current, according to some embodiments of the disclosure.

FIG. 13 is a block diagram of an example computing device that may include one or more memory cells with transistors having increased leakage current in accordance with any of the embodiments disclosed herein.

FIG. 14 is a block diagram of an example processing device that may include one or more memory cells with transistors having increased leakage current in accordance with any of the embodiments disclosed herein.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

A transistor having a gate-to-drain overlap region may have gate-induced drain leakage (GIDL). GIDL is a tunneling-based leakage, which can be caused by the band-to-band tunneling (BTBT) in the gate-to-drain overlap region. GIDL current can increase with increasing Vd (i.e., voltage applied on the drain region) and decreasing Vg (i.e., voltage applied on the gate). GIDL current may be proportional to the size of the gate-drain overlap area. When more impurities are in the drain region, more traps can be formed, which can make the trap-assisted tunneling easier to happen. The or trap-assisted tunneling can result in a higher GIDL current.

GIDL current can be used for a WRITE operation, e.g., in floating body RAM. Compared with the conventional WRITE operation with impact-ionization (II) current, the WRITE operation with GIDL current can achieve lower power consumption and faster WRITE speed. However, GIDL current can decrease with decreasing temperature. Currently available transistors for floating body memory devices suffer from the challenges of getting sufficiently high leakage current (e.g., GIDL current, etc.) at low temperatures.

Embodiments of the present disclosure may improve on at least some of the challenges and issues described above by providing memory cells with transistors having increased leakage current.

In various embodiments of the present disclosure, GIDL current (or the ratio of GIDL current to off current) in transistors is modulated based on the size of the gate-to-drain overlap region, band gaps of semiconductor regions, dopant concentrations in semiconductor regions, work function of drain-side gate, and so on. In some embodiments, the drain region of a transistor includes an underlap portion, which is the portion of the drain region that is under the gate electrode of the transistor. The underlap portion may not be under the drain contact, while the other portion of the drain region may be under the drain contact. The underlap portion may also be referred to as a drain extension. A length of the underlap portion of the drain region may be referred to as the underlap length or underlap distance of the transistor. Different from currently available transistors, the underlap length of an example transistor in the present disclosure is no less than approximately a quarter of the length of the gate electrode (“gate length”). With the larger underlap length, the transistor can have a higher GIDL current.

Additionally or alternatively, the drain region of an example transistor in the present disclosure may have a band gap that is narrower than a band gap of the channel region of the transistor. For instance, the band gap of the channel region may be larger than the band gap of the drain region by at least approximately 0.15 electron volt (eV). The band gap of the drain region may be in a range from approximately 0.35 eV to approximately 1.5 eV. The band gap of the channel region may be in a range from approximately 0.5 eV to approximately 2.5 eV.

A transistor may have an asymmetric source/drain design to increase its GIDL current. In an example, the drain region may be more highly doped than the source region and the channel region. The drain region may have a semiconductor material doped with a dopant concentration that is at least approximately five times of the dopant concentration in the source region or the channel region. The drain region may additionally have another semiconductor material doped with even higher dopant concentration. With the higher dopant concentration(s), extra carriers can be provided in the drain region, which can increase the GIDL current. In another example, the gate electrode of a transistor may include a first portion that is closer to the source region and a second portion that is closer to the drain region. The two portions may be at different electrical potentials. For instance, the voltage of the second portion may be lower than the voltage of the first. As the work function is differentiated, it can be easier to inject carriers into the drain region and access to channel can be easier, which can increase the GIDL current of the transistor.

With the increased GIDL current, the transistors can be used in floating body memory devices that operate at low temperatures. For instance, the floating body memory device can operate at temperatures lower than the room temperature, such as 200 Kelvin (K), 100 K, 50 K, 4 K, and so on.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

Embodiments of the present disclosure are further based on recognition that memory cells with transistors having increased leakage current may be optimized even further if transistors are to be operated at relatively low temperatures, where, as used herein, low-temperature operation (or “lower-temperature” operation) refers to operation at temperatures below room temperature, e.g., below 200 K or lower. Thermal energy is much lower at low temperatures and, consequently, the off-current (loff) of a transistor is much lower and the subthreshold swing is much sharper, compared to room temperature operation. Consequently, if a transistor is operated at low temperatures, its gate length can be shorter than what can be achieved at room temperatures, while keeping the short-channel effects at a level that does not significantly compromise transistor performance. As a result, at low temperatures, it may be possible to further decrease footprints of the transistor arrangements described herein, thereby decreasing their effective gate lengths, while still maintaining adequate performance.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

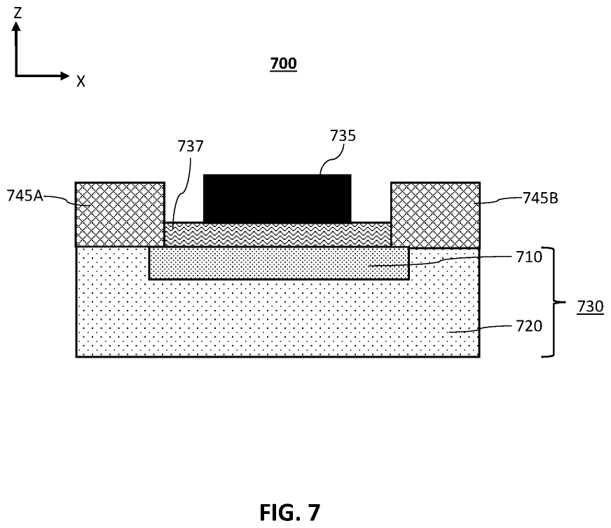

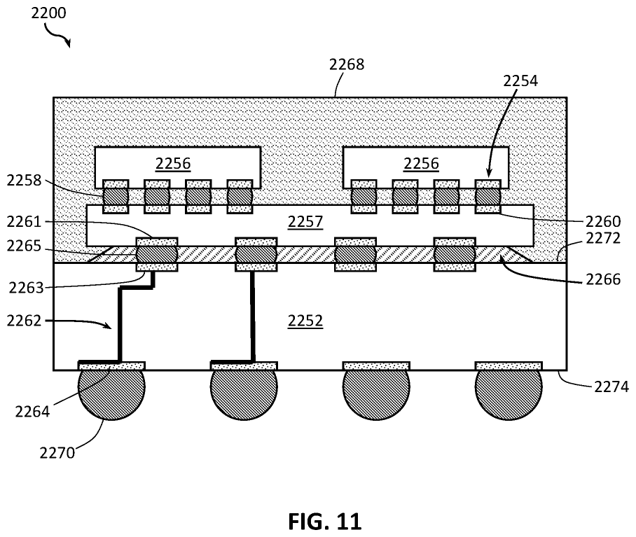

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 11.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of transistors having increased leakage current as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with transistors having increased leakage current as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

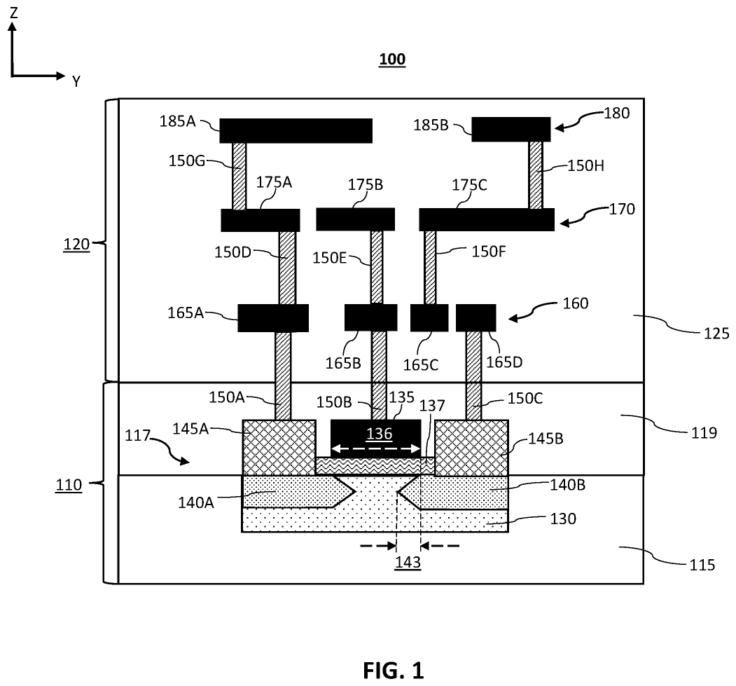

FIG. 1 illustrates an IC device 100 comprising an FEOL section 110 and a BEOL section 120, according to some embodiments of the disclosure. The FEOL section 110 includes a support structure 115, a transistor 117, and an insulative structure 119. The BEOL section 120 includes metal layers 160, 170, and 180 and an insulative structure 125. In other embodiments, the IC device 100 may include fewer, more, or different components. For instance, the FEOL section 110 may include more transistors, or other semiconductor devices not shown in FIG. 1. Also, the BEOL section 120 may include fewer or more metal layers.

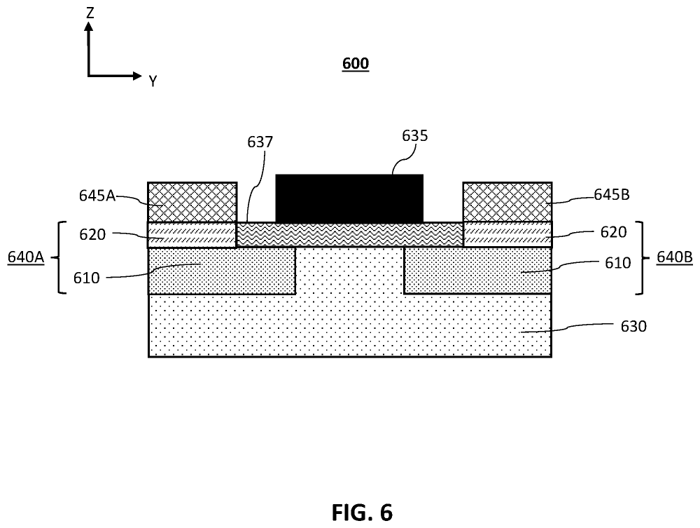

The support structure 115 may be any suitable structure, such as a substrate, a die, a wafer, or a chip, based on which the transistor 117 can be built. The support structure 115 may, e.g., be the wafer 2000 of FIG. 6A, discussed below, and may be, or be included in, a die, e.g., the singulated die 2002 of FIG. 6B, discussed below. In some embodiments, the support structure 115 may be a semiconductor substrate composed of semiconductor material systems including, for example, N-type or P-type materials systems, and, in some embodiments, the channel region 130, described herein, may be a part of the support structure 115. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistor 117 may be built on the support structure 115.

Although a few examples of materials from which the support structure 115 may be formed are described here, any material that may serve as a foundation upon which an IC may be built falls within the spirit and scope of the present disclosure. In various embodiments, the support structure 115 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 115 may provide material “support” in that, e.g., the IC devices/structures described herein are build based on the semiconductor materials of the support structure 115. However, in some embodiments, the support structure 115 may provide mechanical support.

The transistor 117 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. A transistor 117 includes a semiconductor structure that includes a channel region 130, a source region 140A, and a drain region 140B. The semiconductor structure of the transistor 117 may be at least partially in the support structure 115. The support structure 115 may include a semiconductor material, from which at least a portion of the semiconductor structure is formed. The semiconductor structure of the transistor 117 (or a portion of the semiconductor structure, e.g., the channel region 130) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

The channel region 130 includes a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group Ill of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example N-type transistor embodiments (i.e., for the embodiments where the transistor 117 is an NMOS (N-type metal-oxide-semiconductor) transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm−3), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where the transistor 117 is a PMOS (P-type metal-oxide-semiconductor) transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N-or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The source region 140A and the drain region 140B may be connected to the channel region 130. The source region 140A and the drain region 140B may each include one or more doped semiconductor materials. In some embodiments, the source region 140A and the drain region 140B have the same semiconductor material, which may be the same as the channel material of the channel region 130. A semiconductor material of the source region 140A or the drain region 140B may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 140A and the drain region 140B are the same type. In other embodiments, the dopants of the source region 140A and the drain region 140B may be different (e.g., opposite) types. In an example, the source region 140A has N-type dopants and the drain region 140B has P-type dopants. In another example, the source region 140A has P-type dopants and the drain region 140B has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region 140A and the drain region 140B may be highly doped, e.g., with dopant concentrations of about 1.1021 cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 140A and the drain region 140B may be the regions having dopant concentration higher than in other regions, e.g., higher than a dopant concentration in the channel region 130, and, therefore, may be referred to as “highly doped” (HD) regions.

The channel region 130 may include one or more semiconductor materials with doping concentrations significantly smaller than those of the source region 140A and the drain region 140B. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 140A and the drain region 140B, for example below 10¹⁵ cm⁻³ or below 10¹³ cm⁻³. Depending on the context, the term “S/D terminal” may refer to a S/D region or a S/D contact or electrode of a transistor.

The transistor 117 also includes a source contact 145A over the source region 140A and a drain contact 145B over the drain region 140B. The source contact 145A and the drain contact 145B are electrically conductive and may be coupled to source and drain terminals for receiving electrical signals. The source contact 145A or the drain contact 145B includes one or more electrically conductive materials, such as metals. Examples of metals in the source contact 145A and the drain contact 145B may include, but are not limited to, Ru, Cu, Co, palladium (Pd), platinum (Pt), nickel (Ni), and so on. The source contact 145A and drain contact 145B may be referred to as trench contacts or trench electrodes.

The transistor 117 also includes a gate that is over or wraps around the channel region 130. The gate includes a gate electrode 135 and a gate insulator 137. The gate electrode 135 can be coupled to a gate terminal that controls gate voltages applied on the transistor 117. The gate electrode 135 may include one or more gate electrode materials, where the choice of the gate electrode materials may depend on whether the transistor 117 is a P-type transistor or an N-type transistor. For a P-type transistor, gate electrode materials that may be used in different portions of the gate electrode may include, but are not limited to, ruthenium, palladium, platinum, cobalt, nickel, and conductive metal oxides (e.g., ruthenium oxide). For an N-type transistor, gate electrode materials that may be used in different portions of the gate electrode 135, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 135 may include a stack of a plurality of gate electrode materials, where zero or more materials of the stack are work function (WF) materials and at least one material of the stack is a fill metal layer. Further materials/layers may be included next to the gate electrode for other purposes, such as to act as a diffusion barrier layer or/and an adhesion layer.

The gate insulator 137 separates at least a portion of the channel region 130 from the gate electrode 135 so that the channel region 130 is insulated from the gate electrode 135. In some embodiments, the gate insulator 137 may wrap around at least a portion of the channel region 130. The gate insulator 137 may also wrap around at least a portion of the source region 140A or the drain region 140B. At least a portion of the gate insulator 137 may be wrapped around by the gate electrode. The gate insulator 137 includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

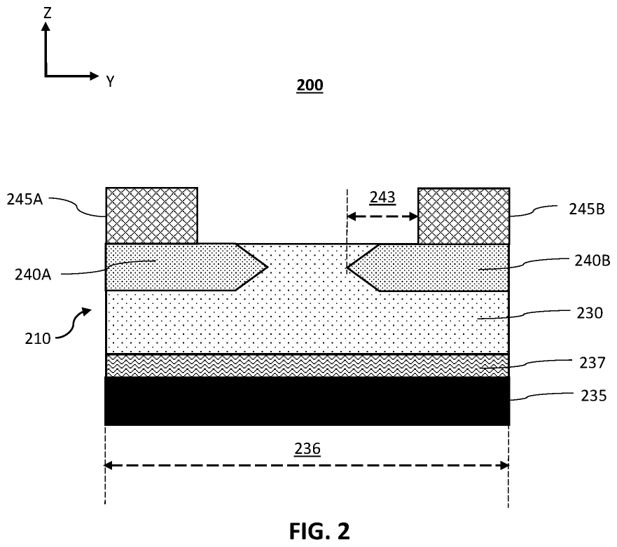

The gate electrode 135 has a gate length 136, which is the length of the gate electrode 135 along the Y axis. In the embodiments of FIG. 1, the gate length 136 is shorter than the length of the gate insulator 137 along the Y axis. Even though not shown in FIG. 1, the gap between the gate electrode 135 and the source contact 145A or the gap between the gate electrode 135 and the drain contact 145B may be filled by one or more dielectric materials, such as oxide. As shown in FIG. 1, the gate electrode 135 and the gate insulator 137 are at the same side of the support structure 115 as the source contact 145A and the drain contact 145B. In other embodiments (e.g., embodiments described below in conjunction with FIGS. 2-5), the location of the gate electrode 135, the gate insulator 137, the source contact 145A, or the drain contact 145B may be different.

In the embodiments of FIG. 1, the gate length 136 may be greater than the effective length of the channel region 130 in FIG. 1. A part of the gate electrode 135 is over a portion of the source region 140A. Another part of the gate electrode 135 is over a portion of the drain region 140B. The length of the drain region 140B along the Y axis is longer than the length of the drain contact 145 along the Y axis. A portion of the drain region 140 is not under the drain contact 145B but is under the gate electrode 135. The portion of the drain region 140B under the gate electrode 135 may be referred to as drain extension, which may be a depletion region. The length of the portion along the Y axis is an underlap length 143. In some embodiments, the underlap length 143 is no less than a quarter of the gate length 136. The underlap length 143 may correspond to the GIDL current of the transistor 117. For instance, the GIDL current of the transistor 117 may increase as the underlap length 143 gets longer. A portion of the source region 140A may also be under the gate electrode 135. The portion of the source region 140A under the gate electrode 135 may be referred to as source extension. The length of the source extension along the Y axis may be the same or similar as the underlap length 143.

In the embodiments of FIG. 1, the transistor 117 is electrically coupled to the metal layer 160. The metal layer 160 is further electrically coupled to the metal layers 170 and 180. The metal layer 160, 170, or 180 may facilitate supply of electrical signals to the transistor 117. Even though not shown in FIG. 1, the metal layer 160, 170, or 180 may be coupled with other devices than the transistor 117, such as diodes, power sources, resistors, capacitors, inductors, sensors, transceivers, receivers, antennas. The transistor 117 and the metal layers 160, 170, and 180 are coupled through vias 150A-150H (collectively referred to as “vias 150” or “via 150”). A via 150 may be electrically conductive. A via 150 may include a metal, such as tungsten (W), molybdenum (Mo), ruthenium (Ru), or other metals. Different vias 150 may include different materials. The vias 150 can provide a conductive channel between the transistor 117 and the metal layer 160 or between two of the metal layers 160, 170, and 180.

The metal layers 160, 170, and 180 are stacked over the transistor 117 along the Y axis. A metal layer 160, 170, or 180 may also be referred to as an interconnect set. A metal layer 160, 170, or 180 may include one or more metal lines. A metal line may also be referred to as an interconnect. The metal layer 160 may be the metal layer that is arranged closest to the FEOL section 110. In some embodiments, the metal layer 160 may be referred to as M0. The metal layer 170 may be referred to as M1. The metal layer 180 may be referred to as M2. There may be one or more metal layers that are arranged on top of the metal layer 180, which may be referred to as M3, M4, and so on. Certain portions of the metal layers 160, 170, and 180 may be insulated from each other by an insulative structure 125. The insulative structure 125 may include one or more electrical insulators. An electrical insulator may be a dielectric material, hysteretic material, and so on. Example dielectric material includes oxide (e.g., Si based oxides, metal oxides, etc.), low-k dielectric, high-k dielectric, and so on. Example hysteretic material include ferroelectric materials, antiferroelectric materials, etc.

The metal layer 160 includes metal lines 165A-165D. For the purpose of illustration, FIG. 1 shows three metal lines in the metal layer 160. In other embodiments, the metal layer 160 may include fewer or more metal lines. Each of the metal lines 165A-165D is an electrically conductive structure. In some embodiments, an individual one of the metal lines 165A-165D includes a metal, such as W, Ru, Mo, or other metals. The metal lines 165A-165D are shown as rectangles in FIG. 1. The metal lines 165A-165C may have different shapes. The metal layer 160 is connected to the transistor 117 through the vias 150A-150C. The vias 150A-150C are separated from each other by one or more electrical insulators in the insulative structure 119. For purpose of illustration, the metal line 165A is connected to the source contact 145A through the via 150A, the metal line 165B is connected to the gate electrode 135 through the via 150B, and the metal line 165D is connected to the drain contact 145B through the via 150C. In other embodiments, the electrical connection between the metal layer 160 and the transistor 117 may be different. The metal layer 160 may facilitate controlling operation of the transistor 117 by providing electrical signals to the source contact 145A, the drain contact 145B, and the gate electrode 135. The metal lines 165A-165D are insulated from each other by one or more electrical insulators in the insulative structure 125. The metal lines 165A-165D may be at different electrical potentials during operation of the IC device 100.

The metal layer 160 is coupled to the metal layer 170 through the vias 150D-150F. The lengths of the vias 150D-150F along the Y axis may be different. For instance, the via 150E may be longer than the via 150D or 150F. In some embodiments, the via 150E and at least a portion of the metal line 160B may be fabricated in a single recess step, in which a metal is provided into an opening to form the via 150E and at least the portion of the metal line 160B. Such a fabrication process may avoid misalignment between the via 150E and the metal line 160B and can achieve seamless contact between the via 150E and the metal line 160B, which can minimize or eliminate interface resistance.

The metal layer 170 includes metal lines 175A-175C. The metal lines 175A-175C are electrically conductive. The metal lines 175A-175C may include one or more metals. A metal in the metal lines 175A-175C may be the same as the metal in one of the metal lines 165A-165D. In the embodiment of FIG. 1, the metal lines 175A-175C are arranged in a same level along the Y axis. The metal lines 175A-175C may be aligned with each other along the X axis. The metal lines 175A-175C may be narrower than the metal lines 165A-165D. In some embodiments, longitudinal axes of the metal lines 175A-175C are in parallel, but the longitudinal axes of the metal lines 175A-175C are not in parallel with longitudinal axes of the metal lines 165A-165D. In an embodiment, the longitudinal axes of the metal lines 175A-175C may be orthogonal (or substantially orthogonal) to the longitudinal axes of the metal lines 165A-165D.

The metal layer 170 is coupled to the metal layer 180 through the vias 150G and 150H. The metal layer 180 incudes metal lines 185A and 185B. The metal lines 185A and 185B may include one or more metals. A metal in the metal lines 185A and 185B may be the same as the metal in one of the metal lines 165A-165D. In the embodiment of FIG. 1, the metal lines 185A and 185B are arranged in a same level along the Y axis. The metal lines 185A and 185B may be aligned with each other along the X axis. The metal lines 185A and 185B may be narrower than the metal lines 165A-165D. The metal lines 185A and 185B may be insulated from each other by the insulative structure 125. In some embodiments, longitudinal axes of the metal lines 185A and 185B are in parallel, but the longitudinal axes of the metal lines 185A and 185B are not in parallel with longitudinal axes of the metal lines 175A-175C. In an embodiment, the longitudinal axes of the metal lines 185A and 185B may be orthogonal (or substantially orthogonal) to the longitudinal axes of the metal lines 175A-175C.

Even though the metal layer 160 in FIG. 1 includes staggered metal lines but the metal layers 170 and 180 does not include staggered metal lines, the metal layer 170 or 180 in other embodiments may include staggered metal lines. Also, the metal layer 160 may include no staggered metal lines. The metal layer 160, 170 or 180 may include a different number of metal lines than the number of metal lines shown in FIG. 1. A metal line may also be referred to as a metal track.

FIG. 2 illustrates an example transistor 200 with increased GIDL current, where a gate electrode 235 is at an opposite side from trench contacts 245A and 245B, according to some embodiments of the disclosure. The transistor 200 also includes a semiconductor structure 210 and a gate insulator 237. The semiconductor structure 210 includes a channel region 230, a source region 240A, and a drain region 240B. The trench contacts 245A and 245B are above the semiconductor structure 210. The gate electrode 235 and gate insulator 237 are below the semiconductor structure 210. The gate electrode 235 has a gate length 236 along the Y axis. The gate insulator 237 separates the substrate 215 from the gate electrode 235. The gate insulator 237 may include one or more electrical insulators, such as the electrical insulators described above in conjunction with FIG. 1. In other embodiments, the transistor 200 may include different, fewer, or more components. The transistor 200 may be used in a floating body RAM, which may operate at low temperatures.

As shown in FIG. 2, a portion of the channel region 230 is between the source region 240A and the drain region 240B along the Y axis. The trench contact 245A is over a portion of the source region 240A. The other portion of the source region 240A may be the source extension. The trench contact 245B is over a portion of the drain region 240B. The other portion of the drain region 240B may be the drain extension. There may be GIDL in the drain extension, as the drain extension is not under the trench contact 245B but is above a portion of the gate electrode 235. The length of the drain extension along the Y axis is an underlap length 243, which is the distance from an edge of the drain region 240B (i.e., the edge touching the channel region 230) to an edge of the trench contact 245B (i.e., the edge closer to the trench contact 245A). The underlap length 243 may be no less than a quarter of the gate length 236.

The channel region 230 may include one or more channel materials, such as the channel materials described above in conjunction with FIG. 1. The source region 240A or drain region 240B may include the same semiconductor material(s) as the channel region 230. In some embodiments, the channel region 230 includes a semiconductor material that has a wider band gap from a semiconductor material in at least part of the drain region 240B (e.g., a semiconductor material in the drain extension). The difference in the band gaps can enable efficient floating body carrier trapping and further increase GIDL current in the transistor 200. In some embodiments, the dopant concentration in the drain region 240B may be higher than the dopant concentration in the source region 240A, which can increase GIDL current on one side, i.e., the side where the drain region 240B is located. More details regarding differentiated band gap or dopant concentration are described below in conjunction with FIGS. 6-8.

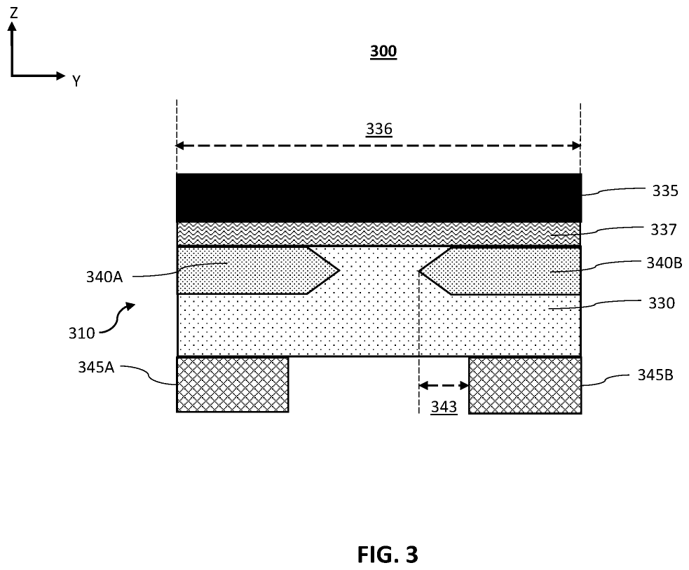

FIG. 3 illustrates another example transistor 300 with increased GIDL current, where a gate electrode 335 is at an opposite side from trench contacts 345A and 345B, according to some embodiments of the disclosure. The transistor 300 also includes a semiconductor structure 310 and a gate insulator 337. The semiconductor structure 310 includes a channel region 330, a source region 340A, and a drain region 340B. The trench contacts 345A and 345B are below the semiconductor structure 310. The gate electrode 335 and gate insulator 337 are above the semiconductor structure 310. The gate electrode 335 has a gate length 336 along the Y axis. The gate insulator 337 separates the substrate 315 from the gate electrode 335. The gate insulator 337 may include one or more electrical insulators, such as the electrical insulators described above in conjunction with FIG. 1. In other embodiments, the transistor 300 may include different, fewer, or more components. The transistor 300 may be used in a floating body RAM, which may operate at low temperatures.

As shown in FIG. 3, a portion of the channel region 330 is between the source region 340A and the drain region 340B along the Y axis. The trench contact 345A is over a portion of the source region 340A. The other portion of the source region 340A may be the source extension. The trench contact 345B is over a portion of the drain region 340B. The other portion of the drain region 340B may be the drain extension. There may be GIDL in the drain extension, as the drain extension is not under the trench contact 345B but is above a portion of the gate electrode 335. The length of the drain extension along the Y axis is an underlap length 343, which is the distance from an edge of the drain region 340B (i.e., the edge touching the channel region 330) to an edge of the trench contact 345B (i.e., the edge closer to the trench contact 345A). The underlap length 343 may be no less than a quarter of the gate length 336.

The channel region 330 may include one or more channel materials, such as the channel materials described above in conjunction with FIG. 1. The source region 340A or drain region 340B may include the same semiconductor material(s) as the channel region 330. In some embodiments, the channel region 330 includes a semiconductor material that has a wider band gap from a semiconductor material in at least part of the drain region 340B (e.g., a semiconductor material in the drain extension). The difference in the band gaps can enable efficient floating body carrier trapping and further increase GIDL current in the transistor 300. In some embodiments, the dopant concentration in the drain region 340B may be higher than the dopant concentration in the source region 340A, which can increase GIDL current on one side, i.e., the side where the drain region 340B is located. More details regarding differentiated band gap or dopant concentration are described below in conjunction with FIGS. 6-8.

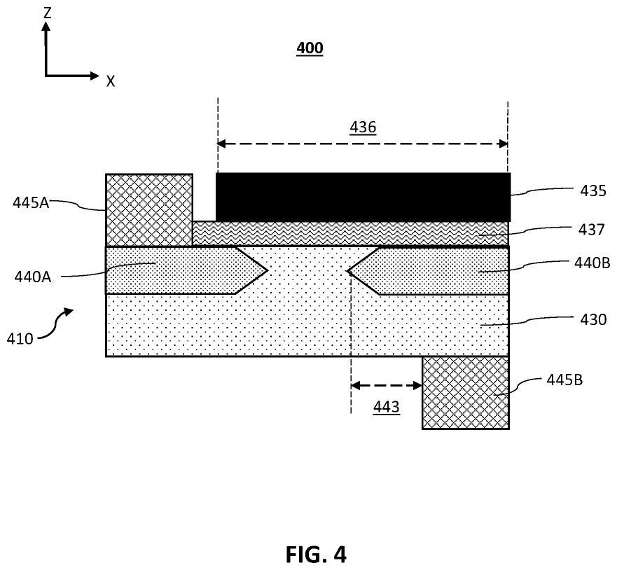

FIG. 4 illustrates an example transistor with increased GIDL current, where trench contacts 445A and 445B are at opposite sides, according to some embodiments of the disclosure. The transistor 400 also includes a semiconductor structure 410 and a gate insulator 437. The semiconductor structure 410 includes a channel region 430, a source region 440A, and a drain region 440B. The trench contact 445A is above the semiconductor structure 410, while the trench contact 445B is below the semiconductor structure 410. The gate electrode 435 and gate insulator 437 are above the semiconductor structure 410. In other embodiments, the trench contact 445A may be below the semiconductor structure 410, while the trench contact 445B may be above the semiconductor structure 410. The gate electrode 435 and gate insulator 437 may also be below the semiconductor structure 410. The transistor 400 may be used in a floating body RAM, which may operate at low temperatures.

The gate electrode 435 has a gate length 436 along the Y axis. The gate insulator 437 separates the substrate 415 from the gate electrode 435. The gate insulator 437 may include one or more electrical insulators, such as the electrical insulators described above in conjunction with FIG. 1. In other embodiments, the transistor 400 may include different, fewer, or more components.

As shown in FIG. 4, a portion of the channel region 430 is between the source region 440A and the drain region 440B along the Y axis. The trench contact 445A is over a portion of the source region 440A. The other portion of the source region 440A may be the source extension. The trench contact 445B is over a portion of the drain region 440B. The other portion of the drain region 440B may be the drain extension. There may be GIDL in the drain extension, as the drain extension is not under the trench contact 445B but is above a portion of the gate electrode 435. The length of the drain extension along the Y axis is an underlap length 443, which is the distance from an edge of the drain region 440B (i.e., the edge touching the channel region 430) to an edge of the trench contact 445B (i.e., the edge closer to the trench contact 445A). The underlap length 443 may be no less than a quarter of the gate length 436.

The channel region 430 may include one or more channel materials, such as the channel materials described above in conjunction with FIG. 1. The source region 440A or drain region 440B may include the same semiconductor material(s) as the channel region 430. In some embodiments, the channel region 430 includes a semiconductor material that has a wider band gap from a semiconductor material in at least part of the drain region 440B (e.g., a semiconductor material in the drain extension). The difference in the band gaps can enable efficient floating body carrier trapping and further increase GIDL current in the transistor 400. In some embodiments, the dopant concentration in the drain region 440B may be higher than the dopant concentration in the source region 440A, which can increase GIDL current on one side, i.e., the side where the drain region 440B is located. More details regarding differentiated band gap or dopant concentration are described below in conjunction with FIGS. 6-8.

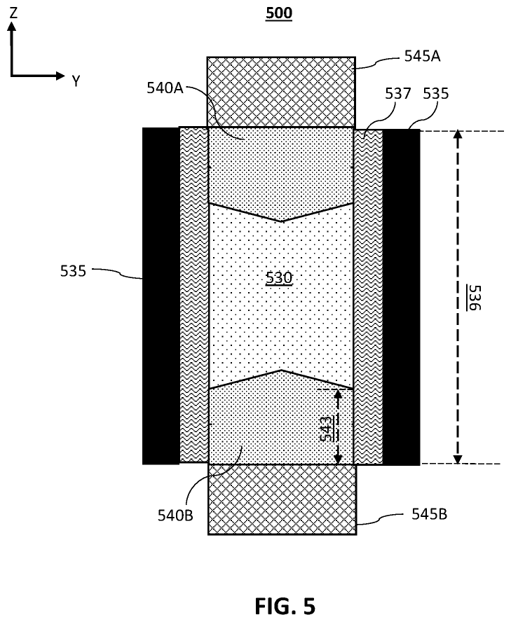

FIG. 5 illustrates an example vertical transistor 500 with increased GIDL current, according to some embodiments of the disclosure. The vertical transistor 500 includes a channel region 530, a source region 540A, and a drain region 540B, gate electrodes 535 (individually referred to as “gate electrode 535”), gate insulators 537 (individually referred to as “gate insulator 537”), a source contact 545A, and a drain contact 545B. In other embodiments, the vertical transistor 500 may include different, fewer, or more components. The vertical transistor 500 may be used in a floating body RAM, which may operate at low temperatures.

As shown in FIG. 5, the channel region 530 is between the source region 540A and the drain region 540B along the Z axis. The source contact 545A is over the source region 540A along the Z axis. The drain contact 545B is over the drain region 540B along the Z axis. The channel region 530, source region 540A, and drain region 540B constitute a semiconductor structure of the vertical transistor 500. Each gate electrode 535 and gate insulator 537 is over the semiconductor structure along the Y axis. The semiconductor structure is between the two gate electrodes 535. In some embodiments, the semiconductor structure may be over a substrate (not shown in FIG. 5) along the Z axis.

Each gate electrode 535 has a gate length 536 along the Z axis. Even though the gate electrodes 535 have the same length in FIG. 5, the gate electrodes 535 may have different lengths in other embodiments. In some embodiments, the two gate electrodes 535 may be two portions of a single conductive structure which may wrap around the semiconductor structure. The gate insulators 537 separate the gate electrodes 535 from the semiconductor structure. A gate insulator 537 may include one or more electrical insulators, such as the electrical insulators described above in conjunction with FIG. 1.

The vertical transistor 500 has an underlap length 543, which is the distance from an edge of the drain region 540B (i.e., the edge touching a gate insulator 537) to an edge of the drain contact 545B (i.e., the edge touching the drain region 540B) along the Z axis. The underlap length 543 may be no less than a quarter of the gate length 536. The vertical design of the semiconductor structure in FIG. 5 can enable a bigger overlap of the drain region 540B with the gate electrodes 535, which can facilitate a longer underlap length 543.

The channel region 530 may include one or more channel materials, such as the channel materials described above in conjunction with FIG. 1. The source region 545A or drain region 540B may include the same semiconductor material(s) as the channel region 530. In some embodiments, the channel region 530 includes a semiconductor material that has a wider band gap from a semiconductor material in at least part of the drain region 540B (e.g., a semiconductor material in the drain extension). The difference in the band gaps can enable efficient floating body carrier trapping and further increase GIDL current in the vertical transistor 500. In some embodiments, the dopant concentration in the drain region 540B may be higher than the dopant concentration in the source region 545A, which can increase GIDL current on one side, i.e., the side where the drain region 540B is located. More details regarding differentiated band gap or dopant concentration are described below in conjunction with FIGS. 6-8.

FIG. 6 illustrates an example transistor 600 with semiconductor materials of different band gaps, according to some embodiments of the disclosure. The transistor 600 includes a channel region 630, a source region 640A comprising a semiconductor structure 610A and a semiconductor structure 620A, a drain region 640B comprising a semiconductor structure 610B and a semiconductor structure 620B, a gate electrode 635, a gate insulator 637, a source contact 645A, and a drain contact 645B. In other embodiments, the transistor 600 may include different, fewer, or more components. The transistor 600 may be used in a floating body RAM, which may operate at low temperatures.

The semiconductor structures 610A and 610B (collectively referred to as “semiconductor structures 610” or “semiconductor structure 610”) each include a first semiconductor material. The semiconductor structures 620A and 620B (collectively referred to as “semiconductor structures 620” or “semiconductor structure 620”) each include a second semiconductor material. The first material may be different from the second material. Also, the first material or the second material may be different from the channel material in the channel region 630. In some embodiments, the channel material may have a narrow band gap that can facilitate high GIDL for programming, e.g., temperature independent programming. The band gap of the channel material may be no greater than approximately 1.5 eV. In some embodiments, the band gap of the channel material may be no less than approximately 0.35 eV. Examples of the channel materials may include InGaAs, InAs, GaAs, InP, Ge, SiGe, and so on.

The first material or the second material may have narrower band gap than the channel material to enable efficient carrier trapping in the floating body. The difference between the band gap of the first material or the second material and the band gap of the channel material may be at least approximately 0.15 eV. The narrow band gap of the first material or the second material, partially the first material or the second material in the underlap portion of the drain region 645B, can increase the GIDL current of the transistor 600. In some embodiments, the narrow band gap of the first material or the second material can enable efficient carrier trapping in the floating body. The floating body may be a semiconductor region under the channel region 630 between the source region 645A and the drain region 645B.

In some embodiments, the second material has a narrower band gap than the first material, and the first material has a narrower band gap than the channel material. The difference between the band gap of the channel material and the band gap of the first material (or the difference between the band gap of the first material and the band gap of the second material) may be at least approximately 0.15 eV. In an example, the channel material may be Si, the first material may be SiGe, the second material may be Ge. In another example, the channel material may be InGaAs, the first material may be InGaAs but with higher atomic ratio of In than the channel material, the second material may be InAs. In other example, the channel material, first material, or second material may be other proper materials.

As shown in FIG. 6, each semiconductor structure 610 is under a semiconductor structure 620 along the Z axis. The source contact 645A is above the semiconductor structure 620A along the Z axis. The drain contact 645B is over the semiconductor structure 620B along the Z axis. A portion of the channel region 630 is between the semiconductor structures 610 along the Y axis. The gate insulator 637, which is above the channel region 630 along the Z axis, is between the semiconductor structures 620 along the Y axis. The gate electrode 635 is above a portion of the gate insulator 637 and a portion of the channel region 630. The gate electrode 635 is also above a portion of the drain region 645B, i.e., an underlap portion. In other embodiments, the locations of the gate electrode 635, gate insulator 637, source contact 645A, or drain contact 645B may be different. For instance, the gate electrode 635, gate insulator 637, source contact 645A, or drain contact 645B may have a location of the gate electrode, gate insulator, source contact, or drain contact shown in any one of FIGS. 2-5. Also, the length of the underlap portion of the drain region 645B along the Y axis may be no less than a quarter of the length of the gate electrode 635 along the Y axis.

FIG. 7 illustrates another example transistor 700 with semiconductor materials of different band gaps, according to some embodiments of the disclosure. The transistor 700 includes a semiconductor structure 710 and a semiconductor structure 720 that constitute a semiconductor region 730, a gate electrode 735, a gate insulator 737, a source contact 745A, and a drain contact 745B. In other embodiments, the transistor 700 may include different, fewer, or more components. The transistor 700 may be used in a floating body RAM, which may operate at low temperatures.

The semiconductor region 730 may include a source region, a drain region, and a channel region between the source region and the drain region. The semiconductor structure 710 includes a first semiconductor material. The semiconductor structure 720 includes a second semiconductor material. The first semiconductor material may be different from the second semiconductor material. Examples of the first semiconductor material may include Si, InP, GaAs, and so on. Examples of the second semiconductor material may include InGaAs, InAs, GaAs, InP, Ge, SiGe, and so on. In an example, the first semiconductor material is Si, while the second semiconductor material is SiGe or Ge. In another example, the first semiconductor material is InP, while the second semiconductor material may be InGaAs. In yet another example, the first semiconductor material is GaAs, while the second semiconductor material is InGaAs.

In some embodiments, the first semiconductor material has a wider band gap than the second material. The difference between the band gaps of the two semiconductor materials may be no less than approximately 0.15 eV. In an example, the band gap of the first semiconductor material may be up to approximately 2.5 eV, while the band gap of the second semiconductor material may be up to approximately 1.5 eV. In some embodiments, the band gap of the first semiconductor material or the second semiconductor material may be no less than approximately 0.35 eV. The wider bandgap in the semiconductor structure 810 may facilitate carrier trapping and therefore, increase the GIDL current of the transistor 700.

In the embodiments of FIG. 7, the semiconductor structure 710 has a portion under the source region 745A and a portion under the drain region 745B. In other embodiments, the semiconductor structure 710 may have no portion under the source region 745A or under the drain region 745B. A height of the semiconductor structure 710 along the Z axis may be smaller than the height of the channel region of the transistor 700.

In the embodiments of FIG. 7, the source contact 745A is above at least part of the source region in the semiconductor region 730 along the Z axis, the drain contact 745B is above at least part of the drain region in the semiconductor region 730 along the Z axis, and the gate electrode 735 is above the channel region in the semiconductor region 730 along the Z axis. The gate insulator 737 separates the gate electrode 735 from the semiconductor region 730. In other embodiments, the locations of the gate electrode 735, gate insulator 737, source contact 745A, or drain contact 745B may be different. For instance, the gate electrode 735, gate insulator 737, source contact 745A, or drain contact 745B may have a location of the gate electrode, gate insulator, source contact, or drain contact shown in any one of FIGS. 2-5. Also, the drain region may include an underlap region that is over the gate electrode 735 along the Z axis. The length of the underlap portion of the drain region along the Y axis may be no less than a quarter of the length of the gate electrode 735 along the Y axis.

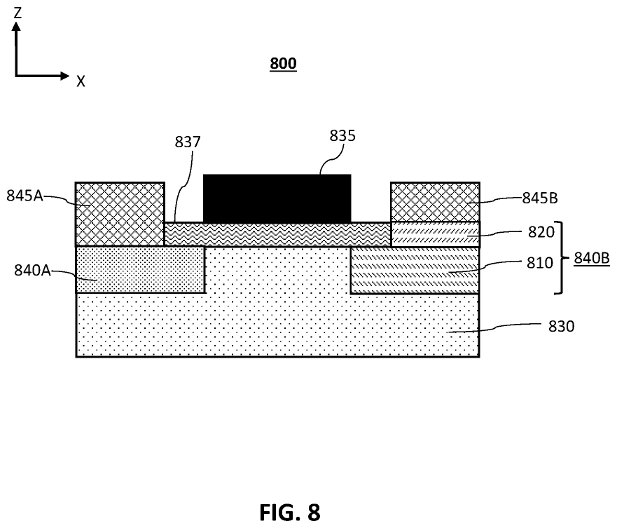

FIG. 8 illustrates an example transistor 800 with asymmetric source and drain, according to some embodiments of the disclosure. The transistor 800 includes a channel region 830, a source region 840A, a drain region 840B including a semiconductor structure 810 and a semiconductor structure 820, a gate electrode 835, a gate insulator 837, a source contact 845A, and a drain contact 845B. In other embodiments, the transistor 800 may include different, fewer, or more components. The transistor 800 may be used in a floating body RAM, which may operate at low temperatures.

The semiconductor structure 810 includes a first doped semiconductor material. The semiconductor structure 820 includes a second doped semiconductor material. The first doped semiconductor material or the second doped semiconductor material may have a higher dopant concentration than the channel material in the channel region 830. In an example, the dopant concentration of the first doped semiconductor material or the second doped semiconductor material may be at least approximately five times the dopant concentration of the channel material. In some embodiments, the second doped semiconductor material may be more highly doped than the first doped semiconductor material. The dopant concentration of the second doped semiconductor material may be at least approximately five times the dopant concentration of the first doped semiconductor material. The high dopant concentration in the drain region 640B may provide excess carriers for increasing GIDL current in the drain region 640B.

The dopant concentration in the source region 640A may be lower than the dopant concentration in the drain region 640B. In some embodiments, the dopant concentration in the source region 640A may be the same or substantially similar as the dopant concentration in the channel region 630.

As shown in FIG. 8, the source contact 845A is above part of the source region 840A along the Z axis, the drain contact 845B is above part of the drain region 840B along the Z axis, and the gate electrode 835 is above the channel region in the semiconductor region 830 along the Z axis. A portion of the gate electrode 835 is above a portion of the drain region 840B, i.e., the underlap portion of the drain region 840B. In the embodiments of FIG. 8, the underlap portion of the drain region 840B is in the semiconductor 810. In other embodiments, at least part of the underlap portion of the drain region 840B may be in the semiconductor structure 820. The gate insulator 837 separates the gate electrode 835 from the channel region 830. In other embodiments, the locations of the gate electrode 835, gate insulator 837, source contact 845A, or drain contact 845B may be different. For instance, the gate electrode 835, gate insulator 837, source contact 845A, or drain contact 845B may have a location of the gate electrode, gate insulator, source contact, or drain contact shown in any one of FIGS. 2-5. Also, the length of the underlap portion of the drain region 840B along the Y axis may be no less than a quarter of the length of the gate electrode 835 along the Y axis.

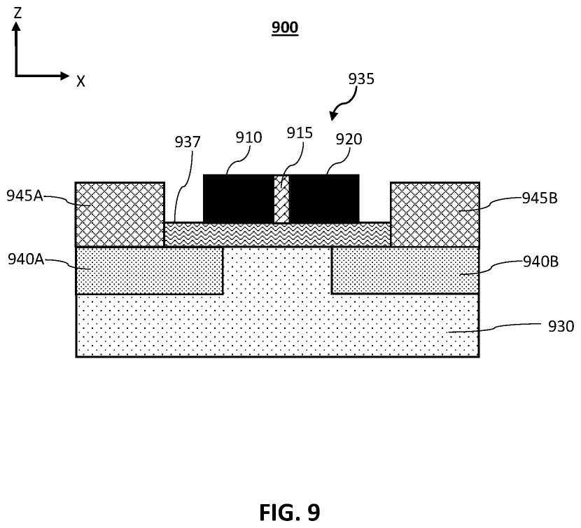

FIG. 9 illustrates an example transistor 900 with a hybrid gate electrode 935, according to some embodiments of the disclosure. The transistor 900 also includes a channel region 930, a source region 940A, a drain region 940B, a gate insulator 937, a source contact 945A, and a drain contact 945B. In other embodiments, the transistor 900 may include different, fewer, or more components. The transistor 900 may be used in a floating body RAM, which may operate at low temperatures.

The hybrid gate electrode 935 includes two gate electrodes 910 and 920 and an electrical insulator 915. The gate electrode 910 is closer to the source region 940A and the source contact 945A than the gate electrode 920, while the gate electrode 920 is closer to the drain region 940B and the drain contact 945B. The two gate electrodes 910 and 920 may each include one or more electrical conductors, such as metal, polycrystalline silicon, and so on. The electrical insulator 915 may include one or more electrically insulating materials, such as dielectric materials. The electrical insulator 915 separates the two gate electrodes 910 and 920 from each other so that the gate electrodes 910 and 920 may be at different electrical potentials during the operation of the transistor 900. In other embodiments, the hybrid gate electrode 930 may include no electrical insulator between the two gate electrodes 910 and 920.

In some embodiments, the two gate electrodes 910 and 920 may include different conductors, which may correspond to different work functions. In some embodiments (e.g., embodiments where the transistor 900 is a N-type transistor and has P-type channel and N-type drain), the work function of the gate electrode 920 may be higher than the work function of the gate electrode 910, e.g., by approximately 0.15 eV to approximately 0.25 eV. The threshold voltage (Vt), i.e., the gate voltage required to turn on the transistor 900, on the gate electrode 920 may be higher than the threshold voltage (Vt) on the gate electrode 910. The higher work function of the gate electrode 920 can result in more ions between the drain contact 945B and the gate electrode 920, which can cause higher injection of carriers into the drain region 940B. More carriers in the drain region 940B can make tunneling easier and therefore, results in a higher leakage current. In other embodiments (e.g., embodiments where the transistor 900 is a P-type transistor and has N-type channel and P-type drain), the work function of the gate electrode 920 may be lower than the work function of the gate electrode 910, e.g., by approximately 0.15 eV to approximately 0.25 eV. The lower work function of the gate electrode 920 for a P-type drain region 940B can facilitate tunneling and increase the GIDL current of the transistor 900.

As shown in FIG. 9, the source contact 945A is above part of the source region 940A along the Z axis, the drain contact 945B is above part of the drain region 940B along the Z axis, and the hybrid gate electrode 935 is above the channel region in the semiconductor region 930 along the Z axis. A portion of the hybrid gate electrode 935 is above a portion of the drain region 940B, i.e., the underlap portion of the drain region 940B. The gate insulator 937 separates the hybrid gate electrode 935 from the channel region 930. In other embodiments, the locations of the hybrid gate electrode 935, gate insulator 937, source contact 945A, or drain contact 945B may be different. For instance, the hybrid gate electrode 935, gate insulator 937, source contact 945A, or drain contact 945B may have a location of the gate electrode, gate insulator, source contact, or drain contact shown in any one of FIGS. 2-5. Also, the length of the underlap portion of the drain region 940B along the Y axis may be no less than a quarter of the length of the gate electrode 935 along the Y axis.

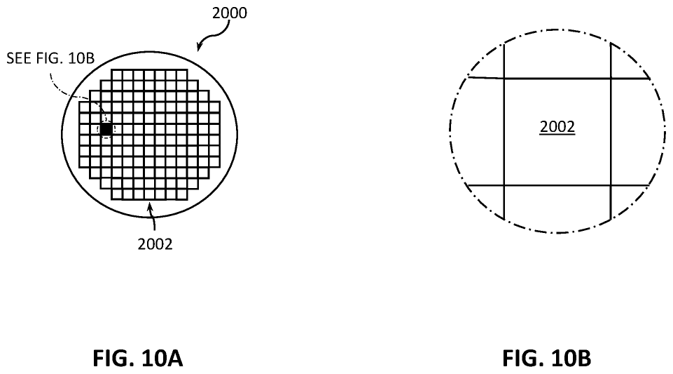

FIGS. 10A-10B are top views of a wafer 2000 and dies 2002 that may facilitate memory cells with transistors having increased leakage current, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 11. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including transistors having increased leakage current as described herein). After the fabrication of the semiconductor product is complete (e.g., after manufacture of transistors having increased leakage current as described herein), the wafer 2000 may undergo a singulation process in which each of the dies 2002 is separated from one another to provide discrete “chips” of the semiconductor product. In particular, devices that include transistors having increased leakage current as disclosed herein may take the form of the wafer 2000 (e.g., not singulated) or the form of the die 2002 (e.g., singulated). The die 2002 may include one or more diodes, one or more transistors as well as, optionally, supporting circuitry to route electrical signals to the III-N diodes with N-doped wells and capping layers and Ill-N transistors, as well as any other IC components. In some embodiments, the wafer 2000 or the die 2002 may implement an electrostatic discharge (ESD) protection device, a radio frequency front-end device, a memory device (e.g., a static random-access memory (SRAM) device), a logic device (e.g., an AND, OR, NAND, or NOR gate), or any other suitable circuit element. Multiple ones of these devices may be combined on a single die 2002.

FIG. 11 is a side, cross-sectional view of an example IC package 2200 that may include one or more IC devices having transistors having increased leakage current, according to some embodiments of the disclosure. In some embodiments, the IC package 2200 may be a system-in-package (SiP).

As shown in FIG. 11, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 11 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 11 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

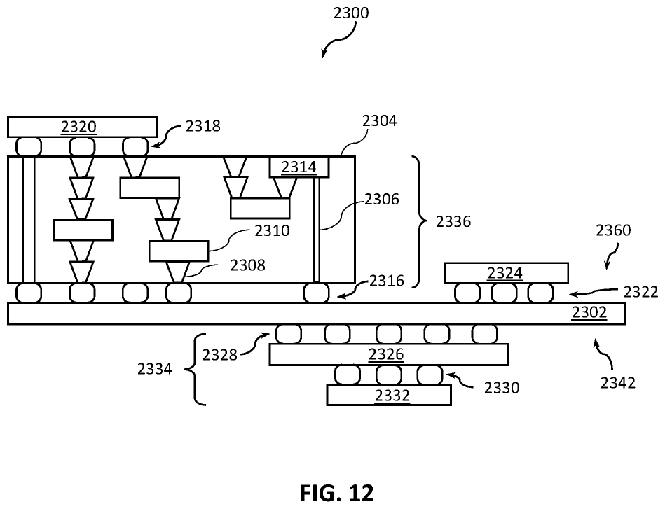

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 11 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 12.

The dies 2256 may take the form of any of the embodiments of the die 2002 discussed herein and may include any of the embodiments of an IC device having transistors having increased leakage current. In embodiments in which the IC package 2200 includes multiple dies 2256, the IC package 2200 may be referred to as a multi-chip package. Importantly, even in such embodiments of an MCP implementation of the IC package 2200, transistors having increased leakage current may be provided in a single chip, in accordance with any of the embodiments described herein. The dies 2256 may include circuitry to perform any desired functionality. For example, one or more of the dies 2256 may be ESD protection dies, including transistors having increased leakage current as described herein, one or more of the dies 2256 may be logic dies (e.g., silicon-based dies), one or more of the dies 2256 may be memory dies (e.g., high bandwidth memory), etc. In some embodiments, any of the dies 2256 may include transistors having increased leakage current, e.g., as discussed above; in some embodiments, at least some of the dies 2256 may not include any III-N diodes with N-doped wells and capping layers.

The IC package 2200 illustrated in FIG. 11 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 11, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 12 is a cross-sectional side view of an IC device assembly 2300 that may include components having one or more IC devices implementing transistors having increased leakage current, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing transistors having increased leakage current in accordance with any of the embodiments disclosed herein; e.g., any of the IC packages discussed below with reference to the IC device assembly 2300 may take the form of any of the embodiments of the IC package 2200 discussed above with reference to FIG. 11 (e.g., may include transistors having increased leakage current in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 12 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 12), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 10B), an IC device (e.g., the IC device of FIGS. 1-2), or any other suitable component. In particular, the IC package 2320 may include transistors having increased leakage current as described herein. Although a single IC package 2320 is shown in FIG. 12, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 12, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF (radio frequency) devices, power amplifiers, power management devices, antennas, arrays, sensors, and microelectromechanical systems (MEMS) devices may also be formed on the interposer 2304. In some embodiments, the IC devices implementing transistors having increased leakage current as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 12 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

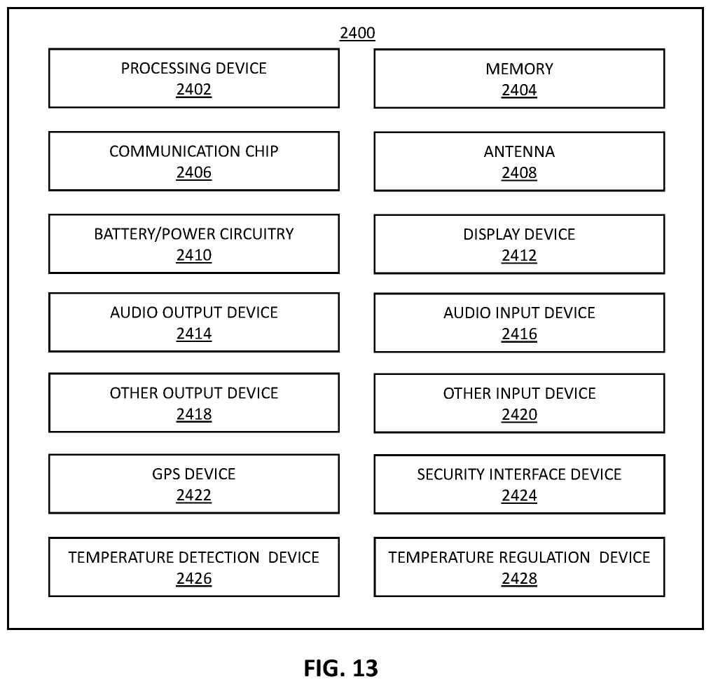

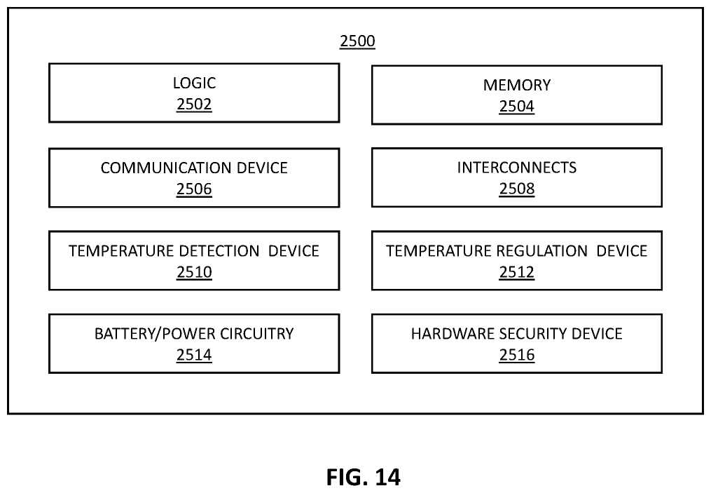

FIG. 13 is a block diagram of an example computing device 2400 that may include one or more components including one or more memory cells with transistors having increased leakage current in accordance with any of the embodiments disclosed herein. For example, any suitable ones of the components of the computing device 2400 may include a die (e.g., the die 2002 of FIG. 14) having one or more memory cells with transistors having increased leakage current as described herein. Any one or more of the components of the computing device 2400 may include, or be included in, an IC package 2200 of FIG. 15 or an IC device 2300 of FIG. 16.

A number of components are illustrated in FIG. 13 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 13, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 14 is a block diagram of an example processing device 2500 that may include one or more memory cells with transistors having increased leakage current in accordance with any of the embodiments disclosed herein. For example, any suitable ones of the components of the processing device 2500 may include a die (e.g., the die 2002 of FIG. 14) having one or more memory cells with transistors having increased leakage current as described herein. Any one or more of the components of the processing device 2500 may include, or be included in, an IC device 2300 (FIG. 16). Any one or more of the components of the processing device 2500 may include, or be included in, an IC package 2200 of FIG. 15 or an IC device 2300 of FIG. 16. Any one or more of the components of the processing device 2500 may include, or be included in, a computing device 2400 of FIG. 13; for example, the processing device 2500 may be the processing device 2402 of the computing device 2400.

A number of components are illustrated in FIG. 14 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 14, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for READ/WRITE operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 13). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member m₁ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 13). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 13 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 13 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 13. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 13. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

The following paragraphs provide various examples of the embodiments disclosed herein.
Example 1 provides an IC device, comprising a semiconductor structure, comprising a source region, a drain region, and a channel region between the source region and the drain region in a first direction; a gate electrode, where a first portion of the gate electrode is over the channel region in a second direction that is substantially perpendicular to the first direction, and a second portion of the gate electrode is over a first portion of the drain region in the second direction; a first contact over a second portion of the drain region; and a second contact over at least part of the source region, where a distance from an edge of the first portion of the drain region to an edge of the gate electrode or to an edge the first contact in the first direction is greater than a fourth of a length of the gate electrode in the first direction.
Example 2 provides the IC device according to example 1, where a band gap of the channel region is equal to or less than approximately 1.5 electron volt.
Example 3 provides the IC device according to example 2, where the band gap of the channel region is at least approximately 0.35 electron volt.
Example 4 provides the IC device according to any of the preceding examples, where the gate electrode is at a first side of the semiconductor structure, the first contact or the second contact is at a second side of the semiconductor structure, and the first side opposes the second side.
Example 5 provides the IC device according to any of the preceding examples, where the first contact is at a first side of the semiconductor structure, the second contact is at a second side of the semiconductor structure, and the first side opposes the second side.
Example 6 provides the IC device according to example 4, where the gate electrode is over the first contact or the second contact in the second direction.
Example 7 provides the IC device according to any of the preceding examples, where the first contact is over the portion of the drain region in the first direction, and the second contact over the portion of the source region in the first direction.
Example 8 provides an IC device, comprising a drain region comprising a first semiconductor material; a source region; a channel region comprising a second semiconductor material, where the channel region is between the source region and the drain region in a first direction; a gate electrode, where a first portion of the gate electrode is over the channel region in a second direction that is substantially perpendicular to the first direction, and a second portion of the gate electrode is over a first portion of the drain region in the second direction; a first contact over a second portion of the drain region; and a second contact over at least part of the source region, where a band gap of the second semiconductor material is greater than a band gap of the first semiconductor material by at least approximately 0.15 electron volt.
Example 9 provides the IC device according to example 8, where the band gap of the second semiconductor material is in a range from approximately 0.35 electron volt to approximately 2.5 electron volt.
Example 10 provides the IC device according to example 8 or 9, where the source region comprises the first semiconductor material.
Example 11 provides the IC device according to any one of examples 8-10, where the drain region further comprises a third semiconductor material, the third semiconductor material over the first semiconductor material in the second direction, and a band gap of the third semiconductor material is narrower than the band gap of the second semiconductor material.
Example 12 provides the IC device according to example 11, where the third semiconductor material is between the first contact and the first semiconductor material in the second direction.
Example 13 provides the IC device according to example 11 or 12, where the source region comprises the first semiconductor material and the third semiconductor material.
Example 14 provides the IC device according to any one of examples 8-13, where a dopant concentration in the drain region is higher than a dopant concentration in the source region.
Example 15 provides an IC device, comprising a semiconductor structure, comprising a source region, a drain region, and a channel region between the source region and the drain region in a first direction; a first gate electrode over a first portion of the channel region in a second direction that is substantially perpendicular to the first direction; a second gate electrode over a second portion of the channel region in a second direction; a first contact over at least part of the drain region; and a second contact over at least part of the source region, where the first portion of the channel region is closer to the source region than the drain region in the first direction, the second portion of the channel region is closer to the drain region than the source region in the first direction, and a work function of the second gate electrode is lower than a work function of the first gate electrode.
Example 16 provides the IC device according to example 15, where the work function of the second gate electrode is lower than the work function of the first gate electrode, and the drain region is N-doped.
Example 17 provides the IC device according to example 16, where the work function of the second gate electrode is lower than the work function of the first gate electrode by approximately 0.15 electron volt to approximately 0.25 electron volt.
Example 18 provides the IC device according to any one of examples 15-17, wherein the work function of the second gate electrode is higher than the work function of the first gate electrode, and the drain region is P-doped.
Example 19 provides the IC device according to example 18, wherein the work function of the second gate electrode is higher than the work function of the first gate electrode by approximately 0.15 electron volt to approximately 0.25 electron volt.
Example 20 provides the IC device according to any one of examples 15-19, further comprising an electrical insulator between the first gate electrode and the second gate electrode.
Example 21 provides an IC package, including the IC device according to any one of examples 1-20; and a further IC component, coupled to the device.
Example 22 provides the IC package according to example 21, where the further IC component includes one of a package substrate, an interposer, or a further IC die.
Example 23 provides the IC package according to example 21 or 22, where the IC device according to any one of examples 1-20 may include, or be a part of, at least one of a memory device, a computing device, a wearable device, a handheld electronic device, and a wireless communications device.
Example 24 provides an electronic device, including a carrier substrate; and one or more of the IC devices according to examples 1-20 and the IC package according to any one of examples 21-23, coupled to the carrier substrate.
Example 25 provides the electronic device according to example 24, where the carrier substrate is a motherboard.
Example 26 provides the electronic device according to example 24, where the carrier substrate is a PCB.
Example 27 provides the electronic device according to any one of examples 24-26, where the electronic device is a wearable electronic device or handheld electronic device.
Example 28 provides the electronic device according to any one of examples 24-27, where the electronic device further includes one or more communication chips and an antenna.
Example 29 provides the electronic device according to any one of examples 24-28, where the electronic device is an RF transceiver.
Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.
Example 31 provides the electronic device according to any one of examples 24-30, where the electronic device is a computing device.
Example 32 provides the electronic device according to any one of examples 24-31, where the electronic device is included in a base station of a wireless communication system.
Example 33 provides the electronic device according to any one of examples 24-31, where the electronic device is included in a user equipment device of a wireless communication system.
Example 34 provides processes for forming the IC device according to any one of claims 1-20.
Example 35 provides processes for forming the IC package according to any one of the claims 21-23.
Example 36 provides processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a semiconductor structure, comprising a source region, a drain region, and a channel region between the source region and the drain region in a first direction;
a gate electrode, wherein a first portion of the gate electrode is over the channel region in a second direction that is substantially perpendicular to the first direction, and a second portion of the gate electrode is over a first portion of the drain region in the second direction;
a first contact over a second portion of the drain region; and
a second contact over at least part of the source region,
wherein a distance from an edge of the first portion of the drain region to an edge of the gate electrode or to an edge the first contact in the first direction is greater than a fourth of a length of the gate electrode in the first direction.

2. The IC device according to claim 1, wherein a band gap of the channel region is equal to or less than approximately 1.5 electron volt.

3. The IC device according to claim 2, wherein the band gap of the channel region is at least approximately 0.35 electron volt.

4. The IC device according to claim 1, wherein:
the gate electrode is at a first side of the semiconductor structure,
the first contact or the second contact is at a second side of the semiconductor structure, and
the first side opposes the second side.

5. The IC device according to claim 1, wherein:
the first contact is at a first side of the semiconductor structure,
the second contact is at a second side of the semiconductor structure, and
the first side opposes the second side.

6. The IC device according to claim 4, wherein the gate electrode is over the first contact or the second contact in the second direction.

7. The IC device according to claim 1, wherein the first contact is over the portion of the drain region in the first direction, and the second contact over the portion of the source region in the first direction.

8. An integrated circuit (IC) device, comprising:
a drain region comprising a first semiconductor material;
a source region;
a channel region comprising a second semiconductor material, wherein the channel region is between the source region and the drain region in a first direction;
a gate electrode, wherein a first portion of the gate electrode is over the channel region in a second direction that is substantially perpendicular to the first direction, and a second portion of the gate electrode is over a first portion of the drain region in the second direction;
a first contact over a second portion of the drain region; and
a second contact over at least part of the source region,
wherein a band gap of the second semiconductor material is greater than a band gap of the first semiconductor material by at least approximately 0.15 electron volt.

9. The IC device according to claim 8, wherein the band gap of the second semiconductor material is in a range from approximately 0.35 electron volt to approximately 2.5 electron volt.

10. The IC device according to claim 8, wherein the source region comprises the first semiconductor material.

11. The IC device according to claim 8, wherein:
the drain region further comprises a third semiconductor material,
the third semiconductor material over the first semiconductor material in the second direction, and
a band gap of the third semiconductor material is narrower than the band gap of the second semiconductor material.

12. The IC device according to claim 11, wherein the third semiconductor material is between the first contact and the first semiconductor material in the second direction.

13. The IC device according to claim 11, wherein the source region comprises the first semiconductor material and the third semiconductor material.

14. The IC device according to claim 8, wherein a dopant concentration in the drain region is higher than a dopant concentration in the source region.

15. An integrated circuit (IC) device, comprising:
a semiconductor structure, comprising a source region, a drain region, and a channel region between the source region and the drain region in a first direction;
a first gate electrode over a first portion of the channel region in a second direction that is substantially perpendicular to the first direction;
a second gate electrode over a second portion of the channel region in a second direction;
a first contact over at least part of the drain region; and
a second contact over at least part of the source region,
wherein the first portion of the channel region is closer to the source region than the drain region in the first direction, the second portion of the channel region is closer to the drain region than the source region in the first direction, and a work function of the second gate electrode is lower than a work function of the first gate electrode.

16. The IC device according to claim 15, wherein the work function of the second gate electrode is lower than the work function of the first gate electrode, and the drain region is N-doped.

17. The IC device according to claim 16, wherein the work function of the second gate electrode is lower than the work function of the first gate electrode by approximately 0.15 electron volt to approximately 0.25 electron volt.

18. The IC device according to claim 15, wherein the work function of the second gate electrode is higher than the work function of the first gate electrode, and the drain region is P-doped.

19. The IC device according to claim 18, wherein the work function of the second gate electrode is higher than the work function of the first gate electrode by approximately 0.15 electron volt to approximately 0.25 electron volt.

20. The IC device according to claim 15, further comprising:
an electrical insulator between the first gate electrode and the second gate electrode.
